(19) United States
(12) Patent Application Publication
(10) Pub. No.: US 2025/0236318 A1
(43) Pub. Date: Jul. 24, 2025

(54) METHOD AND A SYSTEM FOR GENERATING A TRAJECTORY FOR A VEHICLE

(71) Applicant: Y.E. Hub Armenia LLC, Yerevan (AM)

(72) Inventors: Andrei SEREBRO, Saint Petersburg (RU); Aleksandr CHISTIAKOV, Moscow (RU)

(21) Appl. No.: 18/982,649

(22) Filed: Dec. 16, 2024

(30) Foreign Application Priority Data
Jan. 19, 2024 (RU) 2024101314

(51) Int. Cl. B60W 60/00; B60W 30/095

(52) U.S. Cl. CPC B60W 60/00276; B60W 30/0953; B60W 2554/4046

(57) ABSTRACT

A method and server for determining a trajectory for a vehicle are provided. The method comprises: acquiring motion data representative of the vehicle moving in a given road section, generating, based on the motion data, a ground-truth simulated environment for modelling the motion of the vehicle, executing, during a given modelling iteration of the plurality of modelling iterations: generating, based on the motion data, a respective simulated trajectory of the vehicle in the ground-truth simulated environment during the given modelling iteration; determining, based on the respective simulated trajectory, a simulated behavior of a given surrounding object; in response to the respective ground-truth behavior of the given surrounding object during the given modelling iteration being different from the simulated behavior of the given surrounding object: substituting a respective ground-truth behavior of the given surrounding object with the simulated behavior thereof, thereby generating a modified ground-truth simulated environment.

### CROSS-REFERENCE

The present application claims priority to Russian Patent Application No. 2024101314, entitled “Method and a System for Generating a Trajectory for a Vehicle”, filed Jan. 19, 2024, the entirety of which is incorporated herein by reference.

### FIELD

The present technology relates generally to Self-Driving Cars (SDC); and in particular, to a method and a system for generating a trajectory for the SDC using a motion planning algorithm.

### BACKGROUND

Fully or highly automated driving systems may be designed to operate a vehicle on the road without driver interaction (e.g., driverless mode) or other external control. For instance, self-driving vehicles and/or autonomous vehicles are designed to operate a vehicle in a computer-assisted manner.

An autonomous vehicle (such as but not limited to a Self-Driving Car (SDC, for short), a delivery robot, a warehouse robot, and the like) is configured to traverse a planned path between its current position and a target future position without (or with minimal) input from the driver. To that end, the SDC may have access to a plurality of sensors to “perceive” its surrounding area. For example, a given implementation of the SDC can include one or more cameras, one or more LIDARs, and one or more radars. The SDC may further have access to a 3D map to localize itself in the space.

One of the technical challenges associated with the SDC's is their ability to predict, or otherwise determine trajectories of other road users (other vehicles, for example) travelling in the surrounding area of the SDC, for example, in neighbouring lanes. When a given vehicle, travelling, for example, ahead of the SDC in a neighbouring lane, is about to perform a maneuver (such as turning left or right), its trajectory may overlap and/or intersect (at least partially) with the trajectory of the SDC, which may cause high risk of collision between the SDC and one of the other vehicles (including the given one) in the surrounding area. Consequently, this may require the SDC to take corrective measures, be it braking or otherwise active accelerating resulting in building the SDC trajectory ensuring minimal risk of an accident.

Typically, the SDC can be configured to determine the trajectory based on objects located in the current surroundings of the SDC. To that end, for example, the processor of the SDC can be configured to: (i) receive sensed data (such as LIDAR, camera, and other sensor data) of the surroundings of the SDC; (ii) using an object detection machine-learning algorithm (MLA), based on the sensed data, determine locations and object classes (such as vehicle, a passenger, a streetlamp, and the like) of the objects in the surroundings of the SDC; and (iii) determine, based on the respective locations and object classes, behaviors of the surroundings objects. Further, based on the so determined behaviors of the surrounding objects, the processor can be configured to generate the trajectory of the SDC.

The process of generating the trajectory can be executed, by the processor of the SDC iteratively, that is, during each given iteration (lasting, for example, 1, 5, or 10 msec), the processor can be configured to determine the trajectory for the SDC considering the surrounding objects thereof. To do so, the processor of the SDC can be configured to execute a motion planning algorithm. For example, the processor can be configured to generate, during each iteration, a respective trajectory such that the SDC would avoid a collision with the surrounding objects thereof.

One of the technical challenges that the SDC can encounter while traversing a given trajectory is objects of unknown classes, that is, those that the object detection MLA has not been trained to recognize. Another challenge for the SDC can be suddenly appearing objects, that is, those that would require more processing time of the object detection algorithm to recognize them. Either of these situations may lead to navigation errors or accidents associated with the SDC. For example, as a woman pushing a stroller is comparatively less frequently encountered on the road than other pedestrians, the object detection MLA of the SDC can recognize such object as being an inanimate object. In another example, an unusual animal for an area (such as a sheep or a cow in a city, for example), for which the SDC has been trained to operate, may also be recognized as a static object.

As it may be appreciated, training the object detection MLA to detect all object classes, irrespective of operating conditions of the SDC, such as a geographical location, may be ineffective as it would require considerable amount of computational resources, time, and effort on labelling training data set and further training and using such object-detection MLA.

Certain prior art approaches have been proposed to tackle the above-identified technical problem.

U.S. Pat. No. 11,551,414-B2, issued on Jan. 10, 2023, assigned to Magna Autonomous Systems LLC and Woven by Toyota US Inc, and entitled “SIMULATION ARCHITECTURE FOR ON-VEHICLE TESTING AND VALIDATION,” discloses a computing system of a vehicle that generates perception data based on sensor data captured by one or more sensors of the vehicle. The perception data includes one or more representations of physical objects in an environment associated with the vehicle. The computing system further determines simulated perception data that includes one or more representations of virtual objects within the environment and generates modified perception data based on the perception data and the simulated perception data. The modified perception data includes at least one of the one or more representations of physical objects and the one or more representations of virtual objects. The computing system further determines a path of travel for the vehicle based on the modified perception data, which includes the one or more representations of the virtual objects.

U.S. Pat. No. 11,494,533-B2, issued on Nov. 8, 2022, assigned to Waymo LLC, and entitled “SIMULATIONS WITH MODIFIED AGENTS FOR TESTING AUTONOMOUS VEHICLE SOFTWARE,” discloses a simulation software that may be run using log data collected by a vehicle operating in an autonomous driving mode. The simulation may be run using the software to control a simulated vehicle and by modifying a characteristic of an agent identified in the log data. During the running of the simulation, that a first type of interaction between the first simulated vehicle and the modified agent will occur may be determined. In response to determining that the particular type of interaction will occur, the modified agent may be replaced by an interactive agent that simulates a road user corresponding to the modified agent that is capable of responding to actions performed by simulated vehicles. That the particular type of interaction between the simulated vehicle and the interactive agent has occurred in the simulation may be determined.

U.S. Pat. No. 11,338,825-B2, issued on May 24, 2022, assigned to Zoox Inc, and entitled “AGENT BEHAVIOR MODEL FOR SIMULATION CONTROL,” discloses simulating realistic movement of an object, such as a vehicle or pedestrian, that accounts for unusual behavior. The simulating may comprise generating an agent behavior model based at least in part on output of a perception component of an autonomous vehicle and determining a difference between the output and log data that includes indications of an actual maneuver of location of an object. Simulating movement of an object may comprise determining predicted motion of the object using the perception component and modifying the predicted motion based at least in part on the agent behavior model.

### SUMMARY

Therefore, there is a need for systems and methods which avoid, reduce or overcome the limitations of the prior art.

Developers of the present technology have appreciated that sensed data of the SDC representative of rare and abruptly appearing objects can be used for generating a simulated environment, in which new versions of the motion planning algorithm, configured to generate new trajectories for the SDC, can be tested.

More specifically, the developers of the present technology have appreciated that the simulated environment for modelling the motion of the SDC can be generated based on past sensed data indicative of the SDC moving in a given road section including past behaviors of each surrounding object with respect to the SDC, such as a woman pushing a stroller towards a crosswalk intersecting the past SDC's trajectory; or a sheep frantically escaping from a van parked along the road, in which the SDC is travelling.

Further, akin to how the trajectory for the SDC is generated during the runtime, the modelling the motion of the SDC along a given simulated trajectory in the so generated simulated environment can also be executed iteratively. However, to avoid spatial conflicts between the SDC and the surrounding objects in the simulated environment and for a more realistic modelling, the developers have appreciated that the simulated environment can be dynamically updated by adjusting behaviors of the surrounding objects to the current simulated trajectory of the SDC during a given modelling iteration.

In other words, certain non-limiting embodiments of the present technology are directed to: (i) determining, during the given modelling iteration, a respective simulated behavior of a given surrounding object responsive to the current simulated trajectory of the SDC; (ii) determining whether the respective simulated behavior is different from the respective past behavior of the given surrounding object; and if so: (iii) substituting, in the simulated environment, the respective past behavior of the given surrounding object with the respective simulated behavior for at least one subsequently following modelling iteration.

Therefore, the so generated simulated environment may allow for a more realistic modelling the motion of the SDC, considering simulated behaviors of various objects (including unexpected and/or less frequently occurring ones) in the surroundings of the SDC, which May further allow for a more qualitative selection among versions of the motion planning algorithm for further use to generate the trajectories for the SDC during the runtime.

By doing so, the methods and systems described herein may provide for increased safety and comfort of the SDC.

More specifically, in accordance with a first broad aspect of the present technology, there is provided a computer-implemented method for determining a trajectory for a vehicle using a motion planning algorithm. The method comprises: acquiring motion data representative of the vehicle moving in a given road section, the motion data including data of surrounding objects of the vehicle within the given road section; generating, based on the motion data, a ground-truth simulated environment for modelling the motion of the vehicle, the ground-truth simulated environment being representative of a respective ground-truth behavior of each surrounding object of the vehicle in the given road section during a plurality of modelling iterations. Further, during a given modelling iteration of the plurality of modelling iterations, the method comprises executing: generating, based on the motion data, using a current version of the motion planning algorithm, a respective simulated trajectory of the vehicle in the ground-truth simulated environment during the given modelling iteration; determining, based on the respective simulated trajectory, a simulated behavior of a given surrounding object; in response to the respective ground-truth behavior of the given surrounding object during the given modelling iteration being different from the simulated behavior of the given surrounding object: substituting, in the ground-truth simulated environment, for at least one subsequently following modelling iteration of the plurality of modelling iterations, the respective ground-truth behavior of the given surrounding object with the simulated behavior thereof, thereby generating a modified ground-truth simulated environment; using a respective instance of the modified ground-truth simulated environment, from one of the plurality of modelling iterations, for determining trajectories for the vehicle using subsequent versions of the motion planning algorithm.

In some implementations of the method, the generating the ground-truth simulated environment comprises determining, for each surrounding object in the given road section, a respective object class.

In some implementations of the method, the determining the respective object class for each surrounding object comprises soliciting a respective label therefor from a human assessor.

In some implementations of the method, the motion data includes bounding boxes representative of the surrounding objects; and the determining the respective object class for each surrounding object comprises applying a machine-learning algorithm (MLA) that has been trained to determining the respective object class of the given surrounding object based on a respective bounding box representative thereof.

In some implementations of the method, the determining the simulated behavior for the given surrounding object comprises applying an MLA that has been trained to determine actual behaviors of surrounding objects based on a current trajectory of the vehicle.

In some implementations of the method, the substituting comprises substituting until, at a given subsequent modelling iteration of the plurality of modelling iterations, a respective simulated behavior of the given surrounding object corresponds to the respective ground-truth behavior thereof for the given modelling iteration.

In some implementations of the method, the method further comprises: in response to a stopping event during the given modelling iteration: aborting modelling the motion of the vehicle without executing a subsequent modelling iteration; and removing the current version of the motion planning algorithm from further consideration for determining the trajectories for the vehicle.

In some implementations of the method, the stopping event comprises an occurrence of an accident associated with the vehicle during the given modelling iteration.

In accordance with a second broad aspect of the present technology, there is provided a server for determining a trajectory for a vehicle using a motion planning algorithm. The server comprises at least one processor and at least one non-transitory computer-readable memory storing executable instructions, which, when executed by the at least one processor, cause the server to: acquire motion data representative of the vehicle moving in a given road section, the motion data including data of surrounding objects of the vehicle within the given road section; generate, based on the motion data, a ground-truth simulated environment for modelling the motion of the vehicle, the ground-truth simulated environment being representative of a respective ground-truth behavior of each surrounding object of the vehicle in the given road section during a plurality of modelling iterations; execute, during a given modelling iteration of the plurality of modelling iterations: generating, based on the motion data, using a current version of the motion planning algorithm, a respective simulated trajectory of the vehicle in the ground-truth simulated environment during the given modelling iteration; determining, based on the respective simulated trajectory, a simulated behavior of a given surrounding object; in response to the respective ground-truth behavior of the given surrounding object during the given modelling iteration being different from the simulated behavior of the given surrounding object: substituting, in the ground-truth simulated environment, for at least one subsequently following modelling iteration of the plurality of modelling iterations, the respective ground-truth behavior of the given surrounding object with the simulated behavior thereof, thereby generating a modified ground-truth simulated environment; use a respective instance of the modified ground-truth simulated environment, from one of the plurality of modelling iterations, for determining trajectories for the vehicle using subsequent versions of the motion planning algorithm.

In some implementations of the server, to generate the ground-truth simulated environment, the at least one processor causes the server to determine, for each surrounding object in the given road section, a respective object class.

In some implementations of the server, to determine the respective object class for each surrounding object, the at least one processor causes the server to solicit a respective label therefor from a human assessor.

In some implementations of the server, the motion data includes bounding boxes representative of the surrounding objects; and to determine the respective object class for each surrounding object, the at least one processor causes the server to apply a machine-learning algorithm (MLA) that has been trained to determining the respective object class of the given surrounding object based on a respective bounding box representative thereof.

In some implementations of the server, to determine the simulated behavior for the given surrounding object, the at least one processor causes the server to apply an MLA that has been trained to determine actual behaviors of surrounding objects based on a current trajectory of the vehicle.

In some implementations of the server, the substituting comprises substituting until, at a given subsequent modelling iteration of the plurality of modelling iterations, a respective simulated behavior of the given surrounding object corresponds to the respective ground-truth behavior thereof for the given modelling iteration.

In some implementations of the server, in response to a stopping event during the given modelling iteration, the at least one processor further causes the server to: abort modelling the motion of the vehicle without executing a subsequent modelling iteration; and remove the current version of the motion planning algorithm from further consideration for determining the trajectories for the vehicle.

In some implementations of the server, the stopping event comprises an occurrence of an accident associated with the vehicle during the given modelling iteration.

In the context of the present specification, the term “light source” broadly refers to any device configured to emit radiation such as a radiation signal in the form of a beam, for example, without limitation, a light beam including radiation of one or more respective wavelengths within the electromagnetic spectrum. In one example, the light source can be a “laser source”. Thus, the light source could include a laser such as a solid-state laser, laser diode, a high-power laser, or an alternative light source such as, a light emitting diode (LED)-based light source. Some (non-limiting) examples of the laser source include: a Fabry-Perot laser diode, a quantum well laser, a distributed Bragg reflector (DBR) laser, a distributed feedback (DFB) laser, a fiber-laser, or a vertical-cavity surface-emitting laser (VCSEL). In addition, the laser source may emit light beams in differing formats, such as light pulses, continuous wave (CW), quasi-CW, and so on. In some non-limiting examples, the laser source may include a laser diode configured to emit light at a wavelength between about 650 nm and 1150 nm. Alternatively, the light source may include a laser diode configured to emit light beams at a wavelength between about 800 nm and about 1000 nm, between about 850 nm and about 950 nm, between about 1300 nm and about 1600 nm, or in between any other suitable range. Unless indicated otherwise, the term “about” with regard to a numeric value is defined as a variance of up to 10% with respect to the stated value.

In the context of the present specification, the term “surroundings” of a given vehicle refers to an area or a volume around the given vehicle including a portion of a current environment thereof accessible for scanning using one or more sensors mounted on the given vehicle, for example, for generating a 3D map of such surroundings or detecting objects therein.

In the context of the present specification, a “server” is a computer program that is running on appropriate hardware and is capable of receiving requests (e.g. from electronic devices) over a network, and carrying out those requests, or causing those requests to be carried out. The hardware may be implemented as one physical computer or one physical computer system, but neither is required to be the case with respect to the present technology. In the present context, the use of the expression a “server” is not intended to mean that every task (e.g. received instructions or requests) or any particular task will have been received, carried out, or caused to be carried out, by the same server (i.e. the same software and/or hardware); it is intended to mean that any number of software elements or hardware devices may be involved in receiving/sending, carrying out or causing to be carried out any task or request, or the consequences of any task or request; and all of this software and hardware may be one server or multiple servers, both of which are included within the expression “at least one server”.

In the context of the present specification, “electronic device” is any computer hardware that is capable of running software appropriate to the relevant task at hand. In the context of the present specification, the term “electronic device” implies that a device can function as a server for other electronic devices, however it is not required to be the case with respect to the present technology. Thus, some (non-limiting) examples of electronic devices include self-driving unit, personal computers (desktops, laptops, netbooks, etc.), smart phones, and tablets, as well as network equipment such as routers, switches, and gateways. It should be understood that in the present context the fact that the device functions as an electronic device does not mean that it cannot function as a server for other electronic devices.

In the context of the present specification, the expression “information” includes information of any nature or kind whatsoever capable of being stored in a database. Thus, information includes, but is not limited to visual works (e.g. maps), audiovisual works (e.g. images, movies, sound records, presentations etc.), data (e.g. location data, weather data, traffic data, numerical data, etc.), text (e.g. opinions, comments, questions, messages, etc.), documents, spreadsheets, etc.

In the context of the present specification, a “database” is any structured collection of data, irrespective of its particular structure, the database management software, or the computer hardware on which the data is stored, implemented or otherwise rendered available for use. A database may reside on the same hardware as the process that stores or makes use of the information stored in the database or it may reside on separate hardware, such as a dedicated server or plurality of servers.

In the context of the present specification, the words “first”, “second”, “third”, etc. have been used as adjectives only for the purpose of allowing for distinction between the nouns that they modify from one another, and not for the purpose of describing any particular relationship between those nouns. Further, as is discussed herein in other contexts, reference to a “first” element and a “second” element does not preclude the two elements from being the same actual real-world element.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

These and other features, aspects and advantages of the present technology will become better understood with regard to the following description, appended claims and accompanying drawings where:

FIG. 1 depicts a schematic diagram of an example computer system for implementing certain embodiments of systems and/or methods of the present technology;

FIG. 2 depicts a networked computing environment being suitable for use with some implementations of the present technology;

FIG. 3 depicts a LIDAR data acquisition procedure executed by a processor of an electronic device of the networked computing environment of FIG. 2, the procedure for receiving a 3D point cloud data captured by a LiDAR sensor of a vehicle present in the networked computing environment of FIG. 2, in accordance with certain non-limiting embodiments of the present technology;

FIG. 4 depicts a schematic diagram of the vehicle present in the networked computing environment of FIG. 2 driving within a given road section, the given road section being represented by the 3D point cloud data that has been received by the processor of the networked computing environment of FIG. 2 executing the LIDAR data acquisition procedure of FIG. 3, in accordance with certain non-limiting embodiments of the present technology;

FIG. 5 depicts a schematic diagram of a ground-truth simulated environment generated by a server present in the networked computing environment of FIG. 2 based on past sensed data captured by sensors of the vehicle present in the networked computing environment of FIG. 2, in accordance with certain non-limiting embodiments of the present technology;

FIG. 6 depicts a schematic diagram of a modified simulated environment generated by the server present in the networked computing environment of FIG. 2, using the ground-truth simulated environment of FIG. 5, based on simulated trajectories of the vehicle present in the networked computing environment of FIG. 2, in accordance with certain non-limiting embodiments of the present technology;

FIG. 7 depicts a flowchart diagram of a computer-implemented method for determining a trajectory for the vehicle present in the networked computing environment of FIG. 2, in accordance with certain non-limiting embodiments of the present technology.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements which, although not explicitly described or shown herein, nonetheless embody the principles of the present technology and are included within its spirit and scope.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes which may be substantially represented in computer-readable media and so executed by a computer or processor, whether or not such computer or processor is explicitly shown.

The functions of the various elements shown in the figures, including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” or “controller” should not be construed to refer exclusively to hardware capable of executing software, and may implicitly include, without limitation, digital signal processor (DSP) hardware, network processor, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown.

With these fundamentals in place, we will now consider some non-limiting examples to illustrate various implementations of aspects of the present technology.

### Computer System

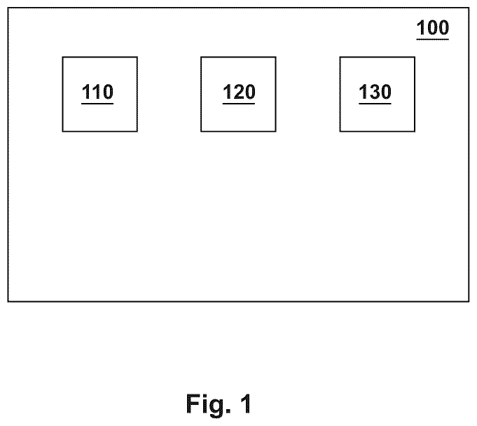

With reference to FIG. 1, there is depicted a schematic diagram of a computer system 100 suitable for use with some implementations of the present technology. The computer system 100 includes various hardware components including one or more single or multi-core processors collectively represented by a processor 110, a solid-state drive 120, and a memory 130, which may be a random-access memory or any other type of memory.

Communication between the various components of the computer system 100 may be enabled by one or more internal and/or external buses (not shown) (e.g. a PCI bus, universal serial bus, IEEE 1394 “Firewire” bus, SCSI bus, Serial-ATA bus, etc.), to which the various hardware components are electronically coupled. According to embodiments of the present technology, the solid-state drive 120 stores program instructions suitable for being loaded into the memory 130 and executed by the processor 110 for determining a presence of an object. For example, the program instructions may be part of a vehicle control application executable by the processor 110. It is noted that the computer system 100 may have additional and/or optional components (not depicted), such as network communication modules, localization modules, and the like.

### Networked Computing Environment

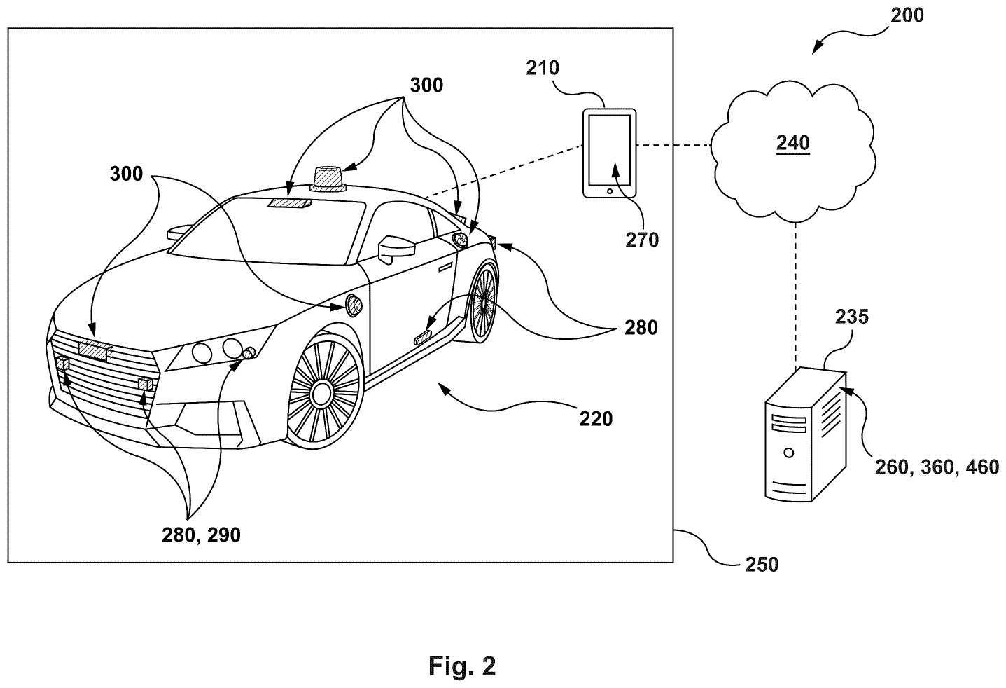

With reference to FIG. 2, there is depicted a networked computing environment 200 suitable for use with some non-limiting embodiments of the present technology. The networked computing environment 200 includes an electronic device 210 associated with a vehicle 220 and/or associated with a user (not depicted) who is associated with the vehicle 220 (such as an operator of the vehicle 220). The environment 200 also includes a server 235 in communication with the electronic device 210 via a communication network 240 (e.g. the Internet or the like, as will be described in greater detail below).

In at least some non-limiting embodiments of the present technology, the electronic device 210 is communicatively coupled to control systems of the vehicle 220. The electronic device 210 could be arranged and configured to control different operations systems of the vehicle 220, including but not limited to: an ECU (engine control unit), steering systems, braking systems, and signaling and illumination systems (i.e. headlights, brake lights, and/or turn signals). In such an embodiment, the vehicle 220 could be a self-driving vehicle.

In some non-limiting embodiments of the present technology, the networked computing environment 200 could include a GPS satellite (not depicted) transmitting and/or receiving a GPS signal to/from the electronic device 210. It will be understood that the present technology is not limited to GPS and may employ a positioning technology other than GPS. It should be noted that the GPS satellite can be omitted altogether.

The vehicle 220, with which the electronic device 210 is associated, could be any transportation vehicle, for leisure or otherwise, such as a private or commercial car, truck, motorbike or the like. Although the vehicle 220 is depicted as being a land vehicle, this may not be the case in each and every non-limiting embodiment of the present technology. For example, in certain non-limiting embodiments of the present technology, the vehicle 220 may be a watercraft, such as a boat, or an aircraft, such as a flying drone.

The vehicle 220 may be user-operated or an autonomous (driver-less) vehicle. In some non-limiting embodiments of the present technology, the vehicle 220 could be implemented as a Self-Driving Car (SDC). It should be noted that specific parameters of the vehicle 220 are not limiting, these specific parameters including, for example: vehicle manufacturer, vehicle model, vehicle year of manufacture, vehicle weight, vehicle dimensions, vehicle weight distribution, vehicle surface area, vehicle height, drive train type (e.g., 2× or 4×), tire type, brake system, fuel system, mileage, vehicle identification number, and engine size.

In other non-limiting embodiments of the present technology, the vehicle 220 may be implemented as a delivery robotic vehicle and be used for transporting various items to a user. In this regard, in some non-limiting embodiments of the present technology, the items may comprise items ordered by the user, such as consumer goods, for example, from an online listing platform (such as a Yandex™ Market™ online listing platform, an Avito™ online listing platform, and the like). In this example, the vehicle 220 may be owned by the online listing platform or by another entity associated with the online listing platform. In yet other non-limiting embodiments of the present technology, the vehicle 220 can be implemented as a warehouse robotic vehicle and be used for at least one of moving, unloading, loading various inventory items in a warehouse.

According to the present technology, the implementation of the electronic device 210 is not limited. For example, the electronic device 210 could be implemented as a vehicle engine control unit, a vehicle CPU, a vehicle navigation device (e.g. TomTom™, Garmin™), a tablet, a personal computer built into the vehicle 220, and the like. Thus, it should be noted that the electronic device 210 may or may not be permanently associated with the vehicle 220. Additionally, or alternatively, the electronic device 210 could be implemented in a wireless communication device such as a mobile telephone (e.g. a smart-phone or a radio-phone). In certain embodiments, the electronic device 210 has a display 270.

The electronic device 210 could include some or all of the components of the computer system 100 depicted in FIG. 1, depending on the particular embodiment. In certain embodiments, the electronic device 210 is an on-board computer device and includes the processor 110, the solid-state drive 120 and the memory 130. In other words, the electronic device 210 includes hardware and/or software and/or firmware, or a combination thereof, for processing data as will be described in greater detail below.

In some non-limiting embodiments of the present technology, the communication network 240 is the Internet. In alternative non-limiting embodiments of the present technology, the communication network 240 can be implemented as any suitable local area network (LAN), wide area network (WAN), a private communication network or the like. It should be expressly understood that implementations for the communication network 240 are for illustration purposes only. A communication link (not separately numbered) is provided between the electronic device 210 and the communication network 240, the implementation of which will depend, inter alia, on how the electronic device 210 is implemented. Merely as an example and not as a limitation, in those non-limiting embodiments of the present technology where the electronic device 210 is implemented as a wireless communication device such as a smartphone or a navigation device, the communication link can be implemented as a wireless communication link. Examples of wireless communication links may include, but are not limited to, a 3G communication network link, a 4G communication network link, and the like. The communication network 240 may also use a wireless connection with the server 235.

In some embodiments of the present technology, the server 235 is implemented as a computer server and could thus include some or all of the components of the computer system 100 of FIG. 1. In one non-limiting example, the server 235 is implemented as a Dell™ PowerEdge™ Server running the Microsoft™ Windows Server™ operating system, but can also be implemented in any other suitable hardware, software, and/or firmware, or a combination thereof. In the depicted non-limiting embodiments of the present technology, the server 235 is a single server. In alternative non-limiting embodiments of the present technology, the functionality of the server 235 may be distributed and may be implemented via multiple servers (not depicted).

In some non-limiting embodiments of the present technology, the processor 110 of the electronic device 210 could be in communication with the server 235 to receive one or more updates. Such updates could include, but are not limited to, software updates, map updates, routes updates, weather updates, and the like. In some non-limiting embodiments of the present technology, the processor 110 can also be configured to transmit to the server 235 certain operational data, such as routes travelled, traffic data, performance data, and the like. Some or all such data transmitted between the vehicle 220 and the server 235 may be encrypted and/or anonymized.

It should be noted that a variety of sensors and systems may be used by the electronic device 210 for gathering information about surroundings 250 of the vehicle 220. As seen in FIG. 2, the vehicle 220 may be equipped with a plurality of sensor systems 280. It should be noted that different sensor systems from the plurality of sensor systems 280 may be used for gathering different types of data regarding the surroundings 250 of the vehicle 220.

In one example, the plurality of sensor systems 280 may include various optical systems including, inter alia, one or more camera-type sensor systems that are mounted to the vehicle 220 and communicatively coupled to the processor 110 of the electronic device 210, such as a camera sensor 290. Broadly speaking, the camera sensor 290 may be configured to gather image data, such as images or a series thereof, about various portions of the surroundings 250 of the vehicle 220.

For example, in specific non-limiting embodiments of the present technology, the camera sensor 290 can be implemented as a mono camera with resolution sufficient to detect surrounding objects at a pre-determined distances of up to about 80 m (although camera systems with other resolutions and ranges are within the scope of the present disclosure) in the surroundings 250 of the vehicle 220. The camera sensor 290 can be mounted on an interior, upper portion of a windshield of the vehicle 220, but other locations are within the scope of the present disclosure, including on a back window, side windows, front hood, rooftop, front grill, or front bumper of the vehicle 220. In some non-limiting embodiments of the present technology, the camera sensor 290 can be mounted in a dedicated enclosure (not depicted) mounted on the top of the vehicle 220.

In some non-limiting embodiments of the present technology, the camera sensor 290 is configured to capture a pre-determine portion of the surroundings 250 around the vehicle 220. In some embodiments of the present technology, the camera sensor 290 is configured to capture the image data that represent approximately 90 degrees of the surroundings 250 around the vehicle 220 that are along a movement path of the vehicle 220.

In other non-limiting embodiments of the present technology, the camera sensor 290 is configured to capture an image (or a series of images) that represent approximately 180 degrees of the surroundings 250 around the vehicle 220 that are along a movement path of the vehicle 220. In yet other non-limiting embodiments of the present technology, the camera sensor 290 is configured to capture the image data that represent approximately 360 degrees of the surroundings 250 around the vehicle 220 that are along a movement path of the vehicle 220 (in other words, the entirety of the surrounding area around the vehicle 220).

In a specific non-limiting example, the camera sensor 290 can be implemented as the camera of a type available from FLIR INTEGRATED IMAGING SOLUTIONS INC., 12051 Riverside Way, Richmond, BC, V6 W 1K7, Canada. It should be expressly understood that the camera sensor 290 can be implemented in any other suitable equipment.

In some cases, the image data provided by the camera sensor 290 could be used by the electronic device 210 for performing object detection procedures, as will be described in detail below.

In another example, the plurality of sensor systems 280 could include one or more radar-type sensor systems (not separately labelled) that are mounted to the vehicle 220 and communicatively coupled to the processor 110 of the electronic device 210. Broadly speaking, the one or more radar-type sensor systems may be configured to make use of radio waves to gather data about various portions of the surroundings 250 of the vehicle 220. For example, the one or more radar-type sensor systems may be configured to gather radar data about potential surrounding objects around the vehicle 220, such data potentially being representative of a distance of surrounding objects from the radar-type sensor system, orientation of surrounding objects, velocity and/or speed of surrounding objects, and the like.

It should be noted that the plurality of sensor systems 280 could include additional types of sensor systems to those non-exhaustively described above and without departing from the scope of the present technology.

For example, according to certain non-limiting embodiments of the present technology and as is illustrated in FIG. 2, the vehicle 220 can be equipped with at least one Light Detection and Ranging (LiDAR) system, such as a LiDAR sensor 300, for gathering information about surroundings 250 of the vehicle 220. While only described herein in the context of being attached to the vehicle 220, it is also contemplated that the LiDAR sensor 300 could be a stand-alone operation or connected to another system.

According to non-limiting embodiments of the present technology, the LiDAR sensor 300 of the vehicle 220 is communicatively coupled to the electronic device 210. In some non-limiting embodiments, information received by the electronic device 210 from the LiDAR sensor 300 could be used, at least in part, in controlling the vehicle 220. For example, in embodiments where the vehicle 220 is a self-driving vehicle, 3D maps created based on information determined by the LiDAR sensor 300 could be used by the electronic device 210 to control, at least in part, the vehicle 220. In another example, the processor 110 of the electronic device 210 can be configured to use the information received by the LiDAR sensor 300 for real-time detection of surrounding objects present in the surroundings 250 of the vehicle 220 for planning motion of the vehicle 220.

In some non-limiting embodiments of the present technology, to plan the motion of the vehicle 220, based on information of the detected surrounding objects, the processor 110 of the electronic device 210 can be configured to generate and/or amend a movement trajectory of the vehicle 220. Also, although most of the examples provided in the description below are detected to the motion planning of the vehicle 220 being generating the movement trajectory thereof, in broader non-limiting embodiments of the present technology, the motion planning of the vehicle 220 can comprise determining, by the processor 110 of the electronic device 210, certain motion parameters of the vehicle 220 at a given future moment in time, such as, at least one of: a displacement, a velocity, and an acceleration of the vehicle 220 at the given future moment in time.

In accordance with certain non-limiting embodiments of the present technology, a given surrounding object can comprise at least one of a moving surrounding object and a stationary surrounding object. For example, a moving surrounding object can include, without limitation, another vehicle, a train, a tram, a cyclist, or a pedestrian. A stationary surrounding object can include, without limitation, a traffic light, a road post, a streetlamp, a curb, a tree, a fire hydrant, a stopped or parked vehicle, and a litter bin, as an example.

It is expected that a person skilled in the art will understand the functionality of the LiDAR sensor 300, but briefly speaking, a light source (such as a laser, not depicted) of the LiDAR sensor 300 is configured to send out light beams that, after having reflected off one or more surrounding objects in the surroundings 250 of the vehicle 220, are scattered back to a receiver (not depicted) of the LiDAR sensor 300. The photons that come back to the receiver are collected with a telescope and counted as a function of time. Using the speed of light (˜3×10⁸ m/s), the processor 110 of the electronic device 210 can then calculate how far the photons have traveled (in the round trip). Photons can be scattered back off of many different entities surrounding the vehicle 220, such as other particles (aerosols or molecules) of water, dust, or smoke in the atmosphere, other vehicles, stationary surrounding objects or potential obstructions in front of the vehicle 220.

Depending on the embodiment, the vehicle 220 could include more or fewer LiDAR sensor 300 than illustrated. Depending on the particular embodiment, choice of inclusion of particular ones of the plurality of sensor systems 280 could depend on the particular embodiment of the LiDAR sensor 300. The LiDAR sensor 300 could be mounted, or retrofitted, to the vehicle 220 in a variety of locations and/or in a variety of configurations.

For example, depending on the implementation of the vehicle 220 and the LiDAR sensor 300, the LiDAR sensor 300 could be mounted on an interior, upper portion of a windshield of the vehicle 220. Nevertheless, as illustrated in FIG. 2, other locations for mounting the LiDAR sensor 300 are within the scope of the present disclosure, including on a back window, side windows, front hood, rooftop, front grill, front bumper or the side of the vehicle 220. In some cases, the LiDAR sensor 300 can even be mounted in a dedicated enclosure mounted on the top of the vehicle 220.

In some non-limiting embodiments of the present technology, such as that of FIG. 2, the LiDAR sensor 300 is mounted to the rooftop of the vehicle 220 in a rotatable configuration. For example, the LiDAR sensor 300 mounted to the vehicle 220 in a rotatable configuration could include at least some components that are rotatable 360 degrees about an axis of rotation of the given LiDAR sensor 300. When mounted in rotatable configurations, the given LiDAR sensor 300 could gather data about most of the portions of the surroundings 250 of the vehicle 220.

In some non-limiting embodiments of the present technology, such as that of FIG. 2, the LiDAR sensor 300 is mounted to the side, or the front grill, for example, in a non-rotatable configuration. For example, the LiDAR sensor 300 mounted to the vehicle 220 in a non-rotatable configuration could include at least some components that are not rotatable 360 degrees and are configured to gather data about pre-determined portions of the surroundings 250 of the vehicle 220.

Irrespective of the specific location and/or the specific configuration of the LiDAR sensor 300, it is configured to capture data about the surroundings 250 of the vehicle 220 used, for example, for building a multi-dimensional map of surrounding objects in the surroundings 250 of the vehicle 220. Details relating to the configuration of the LiDAR sensor 300 to capture the data about the surroundings 250 of the vehicle 220 will now be described.

In a specific non-limiting example, the LiDAR sensor 300 can be implemented as the LiDAR based sensor that may be of the type available from VELODYNE LIDAR, INC. of 5521 Hellyer Avenue, San Jose, CA 95138, United States of America. It should be expressly understood that the LiDAR sensor 300 can be implemented in any other suitable equipment.

It should be noted that although in the description provided herein the LiDAR sensor 300 is implemented as a Time of Flight LiDAR system—and as such, includes respective components suitable for such implementation thereof—other implementations of the LiDAR sensor 300 are also possible without departing from the scope of the present technology. For example, in certain non-limiting embodiments of the present technology, the LiDAR sensor 300 may also be implemented as a Frequency-Modulated Continuous Wave (FMCW) LiDAR system according to one or more implementation variants and based on respective components thereof as disclosed in a co-owned United States Patent Application Publication No.: 2021/373,172-A1 published on Dec. 2, 2021, and entitled “LiDAR DETECTION METHODS AND SYSTEMS”; the content of which is hereby incorporated by reference in its entirety.

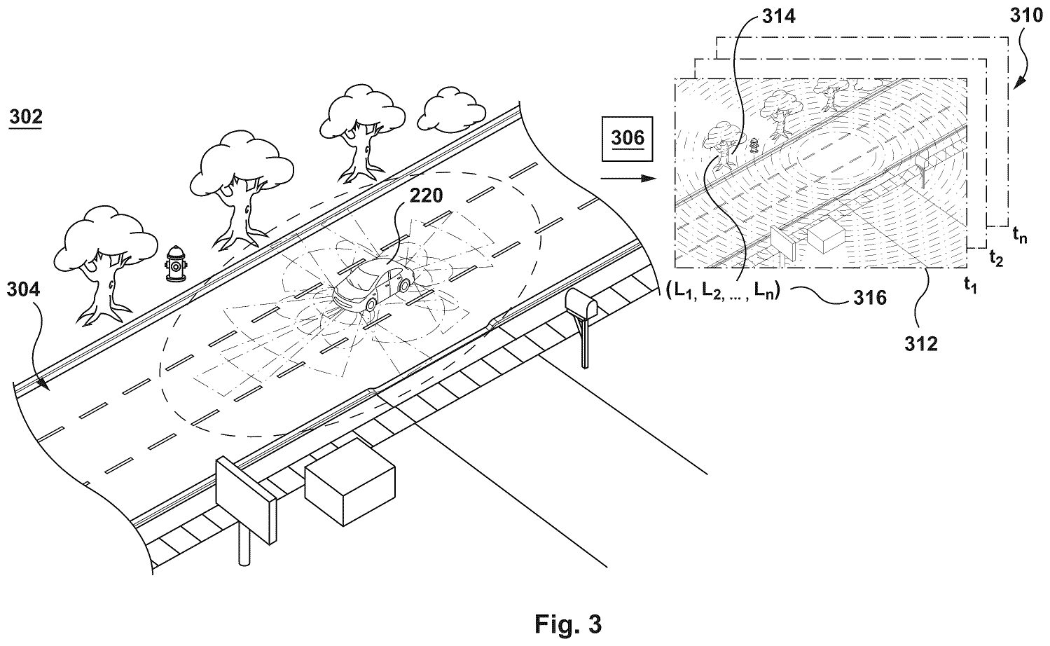

With reference to FIG. 3, there is depicted a schematic diagram of a LiDAR data acquisition procedure 302, executed by the processor 110 of the electronic device 210, for generating a 3D point cloud data 310 representative of surrounding object present in the surroundings 250 of the vehicle 220, in accordance with certain non-limiting embodiments of the present technology.

In some non-limiting embodiments of the present technology, the LiDAR data acquisition procedure 302 of receiving the 3D point cloud data 310 can be executed in a continuous manner. In other embodiments of the present technology, the LiDAR data acquisition procedure 302 of receiving the 3D point cloud data 310 can be implemented at pre-determined intervals, such every 2 milliseconds or any other suitable time interval.

To execute the LiDAR data acquisition procedure 302, as the vehicle 220 travels on a road 304, the processor 110 of the electronic device 210 is configured to acquire, with the LiDAR sensor 300, sensor data 306 representative of the objects in the surrounding area 250 of the vehicle 220. According to certain non-limiting embodiments of the present technology, the processor 110 can be configured to receive the sensor data 306 representative of the objects in the surrounding area 250 of the vehicle 220 at different locations on the road 304 in a form one or more 3D point clouds, such as a 3D point cloud 312.

Generally speaking, the 3D point cloud 312 is a set of LiDAR points in the form of a 3D point cloud, where a given LiDAR point 314 is a point in 3D space indicative of at least a portion of a surface of a given surrounding object on or around the road 304. In some non-limiting embodiments of the present technology, the 3D point cloud 312 may be organized in layers, where points in each layer are also organized in an elliptical fashion and the starting points of all elliptical layers are considered to share a similar orientation.

The given LiDAR point 314 in the 3D point cloud 312 is associated with LiDAR parameters 316 (depicted in FIG. 3 as L1, L2, and LN). As a non-limiting example, the LiDAR parameters 316 may include: distance, intensity, and angle, as well as other parameters relating to information that may be acquired by the LiDAR sensor 300. The LiDAR sensor 300 may acquire a 3D point cloud at each time step t while the vehicle 220 is travelling, thereby acquiring a set of similar 3D point clouds of the 3D point cloud data 310 about the surroundings 250 of the vehicle 220.

It is contemplated that in some non-limiting embodiments of the present technology, the processor 110 of the electronic device 210 can be configured to enrich the 3D point cloud 312 with the image data obtained from the camera sensor 290. To that end, the processor 110 can be configured to apply one or more approaches described in a co-owned U.S. Pat. No. 11,551,365-B2, published on Jan. 23, 2023, and entitled “METHODS AND SYSTEMS FOR COMPUTER-BASED DETERMINING OF PRESENCE OF OBJECTS”; the content of which is hereby incorporated by reference in its entirety.

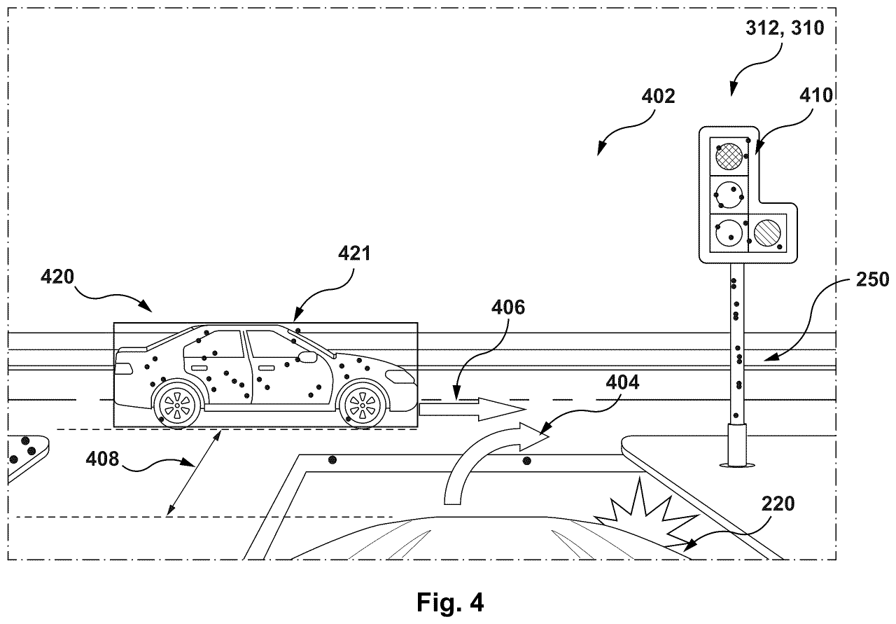

Further, referring back to FIG. 2, using the 3D point cloud 312, the processor 110 can be configured to: (i) detect the objects in the surroundings 250 of the vehicle 220; and (ii) based on the detected objects, determine the movement trajectory for the vehicle 220. With reference to FIG. 4, there is depicted a schematic diagram of the vehicle 220 driving within a given road section 402, in accordance with certain non-limiting embodiments of the present technology.

As it can be appreciated from FIG. 4, as the vehicle 220 approaches an intersection in the given road section 402, it may be configured, according to a predetermined (prior) movement trajectory thereof, to make a right maneuver 404 to an intersecting road. However, to avoid collision with an upcoming vehicle 420 driving down the intersecting road in a straight direction 406, the vehicle 220 must be capable of (i) detecting the upcoming vehicle 420; and (ii) taking certain corrective measures with respect to the prior predetermined movement trajectory, such as one of slowing down, accelerating, or braking, as an example, thereby re-determining the movement trajectory for the vehicle 220.

According to certain non-limiting embodiments of the present technology, to detect the upcoming vehicle 420, the processor 110 can be configured to determine: (i) a location of the upcoming vehicle 420 in a coordinate system of the vehicle 220; and (ii) an object class of the upcoming vehicle 420.

According to certain non-limiting embodiments of the present technology, to adjust the movement trajectory of the vehicle 220 to the current environment thereof and respond to the surrounding object in a timely manner, according to certain non-limiting embodiments of the present technology, the processor 110 of the vehicle 220 can be configured to determine the movement trajectory iteratively. More specifically, during a given iteration (which can comprise 0.1, 1, or 5 msec, for example, or 1, 10, or 20 sec), the processor 110 can be configured to: (1) determine locations and object classes of objects in the surroundings 250, such as those of the upcoming vehicle 402; (ii) determine, based on the respective location and object class, a respective behavior of the upcoming vehicle 420 for the given iteration, such as movement in the straight direction 406; and (iii) based on the respective location, object class, and behavior of the upcoming vehicle 420, generate a respective movement trajectory for the vehicle 220 for the given iteration.

To determine the respective object classes of the surrounding objects, in some non-limiting embodiments of the present technology, the processor 110 can be configured to use a first machine learning algorithm (MLA) 260 hosted by the server 235 and configured to detect the objects in the surroundings 250 of the vehicle 220. In the non-limiting embodiments of the present technology, the first MLA 260 may be based on neural networks (NN), such as convolutional NN (CNN), Transformer-based NN, and the like, which will be described in greater detail below.

According to certain non-limiting embodiments of the present technology, to determine the respective object classes of the surrounding objects, the first MLA 260 can be trained to determine a plurality of object features describing the given surrounding object. Merely as an example, and in no way as a limitation, in case where the given surrounding object is the upcoming vehicle 420, the object features can include, without limitation: (i) a type of the given surrounding object, such as a movable object; (ii) a type of the movable object, such as an inanimate object; (iii) a type of the movable inanimate object, such as a vehicle; (iv) a brand and a model of the upcoming vehicle 420; (v) an issue year of the upcoming vehicle 420; (vi) a body type of the upcoming vehicle 420, such as a sedan, a hatchback, a wagon vehicle, a minivan and others; (vii) a control type of the upcoming vehicle 420, such as traditional (operated by a driver) or driverless (that is, an other SDC); (viii) a current speed of the upcoming vehicle 420 in the straight direction 406; (ix) a distance 408 from the vehicle 220 to the upcoming vehicle 420; and others.

In another example, where the given surrounding object is a pedestrian (not depicted), the object features can include, without limitation: (i) the type of the object, such as a movable object; (ii) the type of the movable object, such as an animate object; (iii) a type of the movable animate object, such as a human being; (iv) a gender of the human being, such as a woman; (v) a height of the pedestrian; (vi) a weight of the pedestrian; (vii) an age group of the pedestrian, such as an adult or a child; (viii) a current movement direction of the pedestrian; (ix) a current speed of the pedestrian in the current movement direction of the pedestrian; (x) a distance to the pedestrian; and others.

In yet other example, in case where the given surrounding object is a traffic light 410, the object features can include, without limitation: (i) the type of the object, such as a stationary object; (ii) a type of the stationary object, such as a traffic regulation object; (iii) a type of the traffic regulation object, such as a traffic light; (iv) a height of the traffic light 410; (v) a distance to the traffic light 410; and others.

In some non-limiting embodiments of the present technology, the server 235 can be configured to train the first MLA 260 using a first training set of data including a first plurality of training digital objects, a given one of which includes: (i) a given training bounding box (such as a bounding box 421 defined around the upcoming vehicle 420) defined around at least one training surrounding object captured in a given portion of the surrounding 250 in a training road section (not depicted); and (ii) a respective feature vector including features representative of the at least one training object; and (iii) a respective label indicative of the location and object class of the at least one training object in a given portion of the surroundings 250. According to certain non-limiting embodiments of the present technology, the features representative of the at least one training object may include, without limitation: (i) a surface area of the given training bounding box; (ii) a number of LiDAR points having fallen within the given training bounding box; (iii) a density of the LiDAR points within the given training bounding box; (iv) light intensity values if each of the LiDAR points having fallen within the given training bounding box; and others.

In some non-limiting embodiments of the present technology, the server 235 can be configured to train the first MLA 260 can be implemented as described in a co-owned Russian Patent Application No.: 2023119351, filed on Jul. 21, 2023, and entitled “METHOD AND A SYSTEM OF DETERMINING A TRAJECTORY FOR AN AUTONOMOUS VEHICLE,” the content of which is incorporated herein by reference in its entirety. However, in other non-limiting embodiments of the present technology, the first MLA 235 can be trained by a third-party server (not depicted), and the server 235 can be configured to gain access to the first MLA 260 either via the communication network 240 or locally.

Further, to determine the respective behavior of the upcoming vehicle 402, during the given iteration, according to certain non-limiting embodiments of the present technology, the processor 110 of the electronic device 210 associated with the vehicle 220 can be configured to use a second MLA 360, which can also be hosted by the server 235, and can be trained to determine behaviors of movable surrounding objects, such as another vehicle or a pedestrian, based on various object features thereof. Akin to the first MLA 260, in some certain non-limiting embodiments of the present technology, the second MLA 360 can also be implemented based on a neural network.

In some non-limiting embodiments of the present technology, the respective behavior of the given movable surrounding object can include, without limitation, starting or continuing to move, stopping, accelerating, decelerating, maneuvering, and the like. Therefore, to train the second MLA 360 to determine the respective behavior of a given movable surrounding object, in some non-limiting embodiments of the present technology, the server 235 can be configured to use a second training set of data, including a second plurality of training digital object, a given one of which includes: (i) training sensed data, received from the plurality of sensor systems 280, representative of a given portion of the surrounding 250 in the training road section (not depicted) during a given training iteration; (ii) a training feature vector including a plurality of training object features of at least one training movable surrounding object present in the given portion of the surroundings 250; and (iii) a respective label representative of a respective training behavior of the at least one training movable surrounding object during the given and subsequently following training iteration.

In some non-limiting embodiments of the present technology, the training sensed data can be past sensed data that the electronic device 210 has generated using the plurality of sensor system 280 during the given training (past) iteration. Therefore, the training road section can be representative of the surroundings 250 of the vehicle 220 during the given training iteration (such as at a given moment in time during the given training iteration), including locations and object classes of respective past objects. To that end, the training sensed data generated at different training iterations can be indicative, for example, of a same past object (such as a traffic light) but captured, by the plurality of sensor systems 280, at different respective perspectives, with different illumination values, or in different relations to other past objects in the training road sections, such as a given past object being obstructed by an other past object or being located in front of (or over) the other past object. Also, the training sensed data during the given training iteration can include, without limitation, data representative of road markings, pedestrian zones (such as crosswalks), snowdrifts, fences, guardrails, and so on.

Further, according to certain non-limiting embodiments of the present technology, the training feature vector can be generated using suitable encoding algorithms configured to represent the training sensed data of the training road section during the given training iteration in a format receivable by the a given implementation of the MLA 360, such as a neural network, as mentioned above.

In some non-limiting embodiments of the present technology, the second MLA 360 can be trained to determine the respective behaviors of the surrounding objects in response to a current movement trajectory of the vehicle 220 from one of the given iteration and at least one previous iteration of the plurality of iterations. In this regard, in these embodiments, the given training digital object of the second plurality of training digital objects can further include data representative of a respective training movement trajectory of the vehicle 220 during one of the given training iteration and at least one previous training iteration. According to certain non-limiting embodiments of the present technology, the data representative of the respective training movement trajectory can include, without limitation, training motion parameters (such as a speed, acceleration, jerk, and the like) of the vehicle 220, data representative of maneuvers, such as lane changes, U-turns, highway exits, and the like.

As it is the case with the first MLA 260, in some non-limiting embodiments of the present technology, the server 235 can be configured to gain access to the second MLA 360 that has been trained by the third-party server (not depicted) via the communication network 240.

Further, to generate the respective movement trajectory of the vehicle 220 based on the respective behavior of the upcoming vehicle 402, for the given iteration, according to certain non-limiting embodiments of the present technology, the processor 110 can be configured to execute a motion planning algorithm 460. Broadly speaking, the motion planning algorithm 460 can be configured to generate, for each iteration, the respective trajectory for the vehicle 220 based on at least one of: respective locations, object classes, and behaviors of the objects in the surroundings 250. More specifically, continuing with the example of FIG. 4, using the motion planning algorithm 460, the processor 110 can be configured to determine current object kinematic data, including current object motion parameters (such as current velocity, acceleration, jerk, braking profile, and the like) of the upcoming vehicle 402 in the straight direction 406. Further, based on the current object kinematic data, the processor 110 can be configured to: determine current vehicle kinematic data of the vehicle 220 for the given iteration, cause the vehicle 220 to move, with the current vehicle kinematic data, along the direction of the right maneuver 404 so as to avoid a collision with the upcoming vehicle 402 and/or with any other object in the surroundings 250.

In some non-limiting embodiments of the present technology, the motion planning algorithm 460 can include a kinematic model. Broadly speaking, the kinematic model 402 comprises a combination of mathematical models configured to calculate the current object kinematic data for the surrounding objects of the vehicle 220. In some non-limiting embodiments of the present technology, the kinematic model can be implemented as described in a co-owned U.S. Pat. No. 11,753,037-B2, issued on Sep. 12, 2023, and entitled “METHOD AND PROCESSOR FOR CONTROLLING IN-LANE MOVEMENT OF AUTONOMOUS VEHICLE,” the content of which is incorporated herein by reference in its entirety. Other implementation of the motion planning algorithm 460, such as those including an MLA, are envisioned without departing from the scope of the present technology. As will become apparent from the description provided hereinbelow, there can be multiple versions of the motion planning algorithm 460 that can be uploaded to the electronic device 210 for executing by the processor 110 for generating motion trajectories for the vehicle 220. Each of the versions of the motion planning algorithm 460 can be configured to generate, for a given motion direction, such as the right maneuver 404 as exemplified in FIG. 4, movement trajectories differently, which can include different curvatures and vehicle kinematic data.

However, one of the challenges that can be encountered while the vehicle 220 is traversing a given route is abruptly appearing or unknown objects to the first MLA 260. For examples, unknown objects can include, without limitation, objects of comparatively rarely encountered object classes, such as a person pushing a stroller, a person in a wheelchair, cattle (such as sheep, swine, or cow, especially in a city area). On the other hand, the abruptly appearing objects can include objects that are not visible to the plurality of sensor systems 280 of the vehicle during a portion of the given iteration, for example, due to being obstructed by other objects. Such objects can include objects moving at comparatively high speed, such as, without limitation, a fleeing animal, a cyclist, or another vehicle. Therefore, when these objects become visible to the plurality of sensor systems 280 only at some point during the given iteration, the processor 110 may not have sufficient time to determine their object classes, behaviors, and current object kinematic data of these objects, which can cause inaccurate determination of the respective trajectory for the vehicle 220.

One of the straight-forward solutions to the above-identified technical problem would be (i) training the first and second MLAs 260, 360 for detecting objects of all possible object classes and further determining behaviors of these objects, respectively; and (ii) test new versions of the motion planning algorithm 460 based on the predictions of the first and second MLAs 260, 360 for these specific objects. However, as it can be appreciated, training the first and second MLAs 260, 360 to detect and determine behaviors of more objects may require (i) considerable time and effort for labelling respective data sets; as well as (ii) computational resources of the server 235 and/or processor 110 of the electronic device 210 to train and use the first and second MLAs 260, 360.

Thus, developers of the present technology have appreciated that the sensed data, generated by the plurality of sensor systems 280 in the past, representative of such specific objects can be used for generating a simulated environment where different versions of the motion planning algorithm 460 can be tested. The versions of the motion planning algorithm 460 can be used for generating different simulated trajectories which can further be analyzed for safety. Further, versions of the motion planning algorithm 460 that generated modelled trajectories have been determined safe, can further be used for generating the motion trajectories of the vehicle 220 during the runtime.

How the simulated environment can be generated, according to certain non-limiting embodiments of the present technology, will now be described.

### Simulated Environment

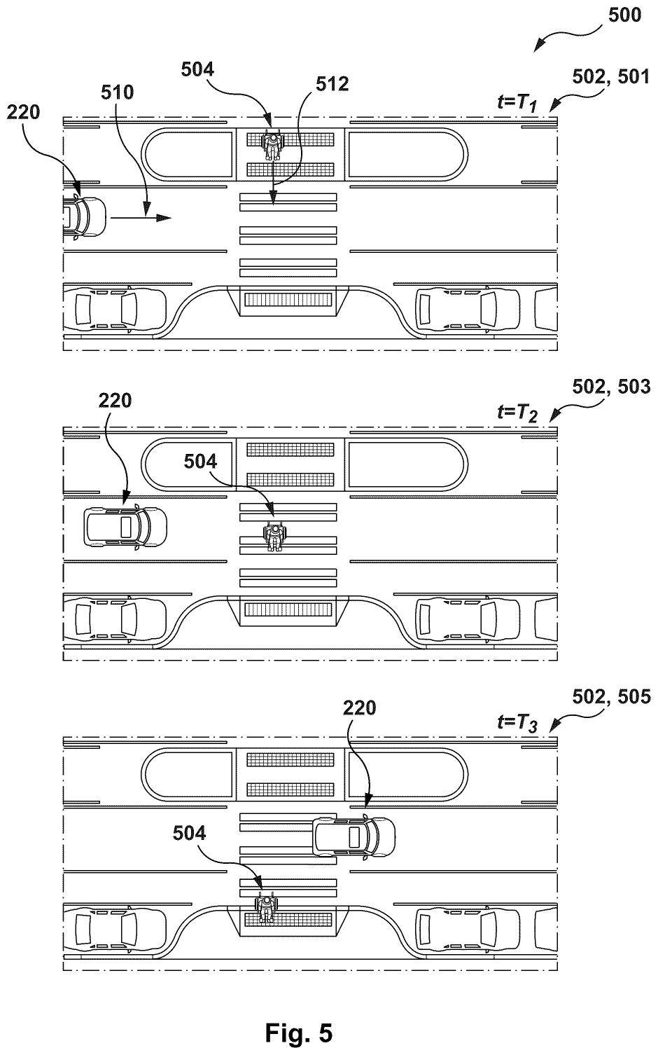

With reference to FIG. 5, there is schematically depicted a ground-truth simulated environment 500, generated by the server 235, and representative of the vehicle 220 travelling within a past road section 502 during a first, second, and third past iterations 501 (T₁), 503 (T₂), and 505 (T₃), in accordance with certain non-limiting embodiments of the present technology. As it can be appreciated, in the illustrated example, the vehicle 220 travelled down the past road section 502 in a first direction 510, that is, in a forward direction of the vehicle 220, which is, from left to right in the orientation of FIG. 5.

According to certain non-limiting embodiments of the present technology, to generate the ground-truth simulated environment 500, the server 235 can be configured to use the past sensed data generated by the plurality of sensor systems 280 of the vehicle 220 and received by the processor 110 of the electronic device 210. As mentioned hereinabove, the past sensed data can include: data indicative of locations of past surrounding objects, object classes of the past surrounding objects, and behaviors of the past surrounding objects during each past iteration of a plurality of past iterations, such as the first, second, and third past iteration 501, 503, and 505.

In some non-limiting embodiments of the present technology, the server 235 can be configured to determine the object classes of the past surrounding object using the first MLA 260 trained as mentioned above. In other non-limiting embodiments of the present technology, the server 235 can be configured to solicit human generated labels representative of the object classes of the past surrounding objects from human assessors. For example, in these embodiments, the server 235 can be configured to submit, via the communication network 240, the past sensed data in a computer-readable format to a crowdsourcing platform (such as a Yandex™ Toloka™ crowdsourcing platform or an Amazon™ Mechanical Turk™ crowdsourcing platform) with a respective labelling mandate. For example, if using the first MLA 260, the server 235 could not recognize a given object 504 as being a person in a wheelchair, the server 235 can be configured to acquire a label for the given object 504 from a human assessor.

Thus, as illustrated in FIG. 5, the given object 504 (the person in a wheelchair) is crossing the past road section 502 before the vehicle 220 in a second direction 512, which is perpendicular to the first direction 510. Accordingly, for each one of the first, second, and third past iterations 501, 503, and 505, the processor 110 of the electronic device 210 could be configured to: (i) detect, using the first MLA 260, the given object 504; (ii) determine, using the second MLA 360, the respective past behavior of the given object 504 intended to cross the past road section 502 at a crosswalk (not separately numbered) in the second direction 512; and (iii) based on the respective past behaviors, determine, using a past version of the motion planning algorithm 460, past kinematic data for the vehicle 220 defining a respective past trajectory thereof during each one of the first, second, and third past iterations 501, 503, and 505. As illustrated in the example of FIG. 5, each one of the past trajectories of the vehicle 220 included yielding the road to the given object 504.

Thus, by generating the ground-truth simulated environment 500 using the past sensed data, the server 235 can be configured to model the past actual motion of the vehicle 220 and respective past behaviors of the past surrounding objects in the past road section 502. In some non-limiting embodiments of the present technology, the server 235 can be configured to generate the ground-truth simulated environment 500 as a 2D simulated environment, representative of movements of the vehicle 220 and the past surrounding objects in the past road section 502 in a given projection-such as in a top plan view, as schematically depicted in FIG. 5. In these embodiments, the ground-truth simulated environment 500 can be represented as a sequence of images representative of locations of the vehicle 220 and the past surrounding objects in the past road section 502 at each past iteration. In other non-limiting embodiments of the present technology, the server 235 can be configured to generate the ground-truth simulated environment 500 as a 3D simulated environment, where the vehicle 220 and the past surrounding objects are represented as 3D models comprising, for example, mesh elements.

Further, according to certain non-limiting embodiments of the present technology, the server 235 can be configured to use the ground-truth simulated environment 500 for testing new versions of the motion planning algorithm 460 for further use in generating new trajectories for the vehicle 220. In some non-limiting embodiments of the present technology, the server 235 can be configured to cause simulation of these new trajectories in the ground-truth simulated environment 500 prior to using them for the actual movement of the vehicle 220.

A given simulated trajectory for the vehicle 220 in the past road section 502 can be different from the past trajectory in at least one of: (i) kinematic data of the vehicle 220; and (ii) a geometry of a path defined by the given simulated trajectory. More specifically, by modifying the past kinematic data of the vehicle 220, the server 235 can be configured to cause the vehicle 220 to move in the first direction 510 in at least one of the following manners: (1) slower or faster; (2) with acceleration or deceleration; and (3) with higher or less jerk. On the other hand, by modifying the geometry of the past trajectory, the server 235 can be configured to cause the vehicle 220 to deviate from the first direction 510. For example, using one of the new versions of the motion planning algorithms 460, the server 235 can be configured to cause the vehicle 220, during a given one of modelling iterations, to change lanes.

Once the server 235 has generated the given simulated trajectory for the vehicle 220, the server 235 can further be configured to cause a respective modeled motion of the vehicle 220 in the ground-truth simulated environment 500. However, the respective modelled motion of the vehicle 220 can cause conflicts with the movements of the past surrounding objects in the ground-truth simulated environment 500. For example, if the given simulated trajectory, during at least one of the first, second, and third past iterations 501, 503, and 505, includes causing the vehicle 220 to move at a higher speed, representations of the vehicle 220 and that of the given object 504 can overlap in the ground-truth simulated environment 500. Such modelling of the motion of the vehicle 220 may have a lower value for testing the new versions of the motion planning algorithm 460 as this simulation may not allow determining how the surrounding objects react to the changed trajectory of the vehicle 220 and whether the modelled trajectories are safe and/or comfortable for the passengers of the vehicle 220 and other road users.

Therefore, the developers of the present technology have appreciated that in order to model the motions of the vehicle 220 more realistically and estimate comfort and safety of the simulated trajectories, the ground-truth simulated environment 500 can be dynamically adjusted in response to the given simulated trajectory of the vehicle 220. In other words, according to non-limiting embodiments of the present technology, in response to each new simulated trajectory of the vehicle 220, the server 235 can be configured to re-determine behaviors of the surrounding objects in the ground-truth simulated environment 500 at each modelling iteration, thereby generating a modified simulated environment, such as a modified simulated environment 600.

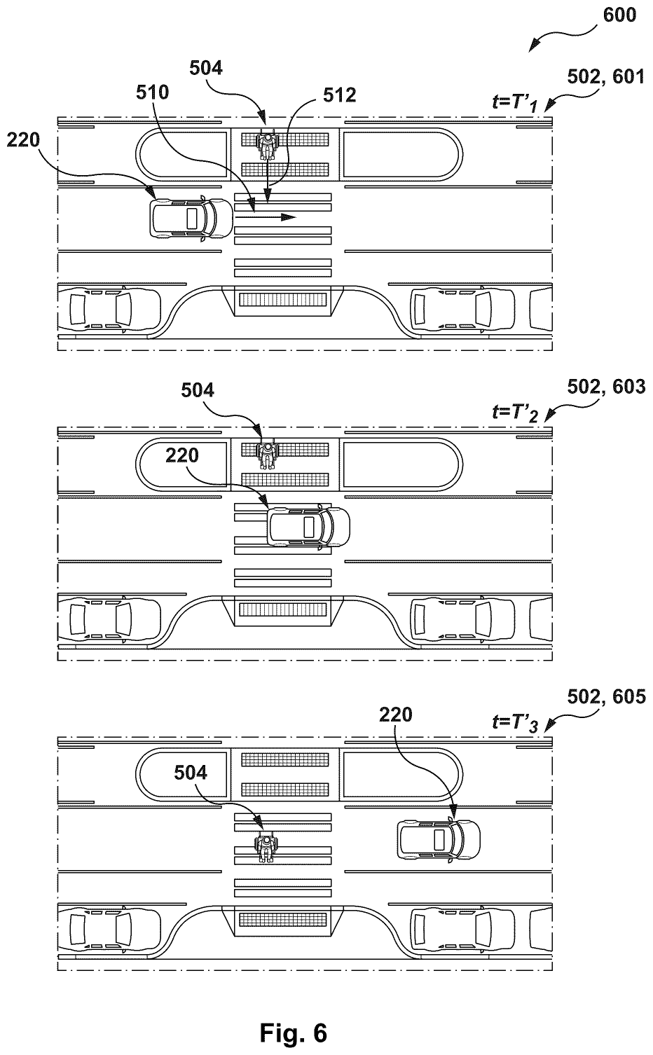

With reference to FIG. 6, there is schematically depicted the modified simulated environment 600, generated by the server 235 using a given new version of the motion planning algorithm 460, during first, second, and third modelling iterations 601 (Tr), 603 (T₂), and 605 (T₃), in accordance with certain non-limiting embodiments of the present technology. According to certain non-limiting embodiments of the present technology, a given modelling iteration of a plurality of modelling iterations, such as one of the first, second, and third modelling iterations 601, 603, and 605, can correspond in duration to a respective past iteration. In some non-limiting embodiments of the present technology, the given modelling iteration can be either shorter or longer in duration than the respective past iteration.

In the example illustrated in FIG. 6, initial positions of the vehicle 220 and the given object 504 in the past road section 502, that is, positions thereof in the beginning of the first modelling iteration 601, correspond to initial positions of the vehicle 220 and the given object 504 in the beginning of the first past iteration 501 in the ground-truth simulated environment 500.

Further, during the first modelling iteration 601, using the given new version of the motion planning algorithm 460, based on the past sensed data (which the server 235 has used for generating the ground-truth simulated environment 500), the server 235 can be configured to generate a first simulated trajectory for the vehicle 220, which is defined by first modelled kinematic data for the vehicle 220 and the first direction 510. With continued reference to FIG. 6 and with back reference to FIG. 5, as it can be appreciated, with the first modelled kinematic data, the vehicle 220 moves faster in the first direction 510 during the first modelling iteration 601 than with the past kinematic data during the first past iteration 501.

Further, using the second MLA 360, based on the first simulated trajectory, the server 235 can be configured to determine a first simulated behavior for the given object 504 for the first modelling iteration 601. For example, the server 235 can be configured to determine that, as the vehicle 220 moves along the first simulated trajectory comparatively fast, to avoid a collision with the vehicle 220, during the first modelling iteration 601, the given object 504 must not move in the second direction 512, and, rather, must be resting in the initial position.

Further, according to certain non-limiting embodiments of the present technology, the server 235 can be configured to determine whether the first simulated behavior of the given object 504 differs from the respective past behavior thereof in the ground-truth simulated environment 500. As it can be appreciated, in the current examples, the respective past behavior of the given object 504 during the first past iteration 501 (corresponding to the first modelling iteration 601) was to cross the past road section 502 in the second direction 512; whereas in the modified simulated environment 600, the given object 504 is resting during the first modelling iteration 601.

Thus, in response to determining that the first simulated behavior of the given object 504 is different from the respective past behavior thereof during the first modelling iteration 601, in some non-limiting embodiments of the present technology, the server 235 can be configured to substitute the respective past behavior of the given object 504 with the first simulated behavior for at least one subsequently following modelling iteration of the plurality of modelling iterations. In some non-limiting embodiments of the present technology, the server 235 can be configured to substitute the respective past behavior of the given object 504 for a predetermined number of subsequent modelling iterations, such as 1, 5, or 10. Once the predetermined number of subsequent modelling iterations has passed, during a following modelling iteration, the server 235 can be configured to: (i) re-determine a respective simulated behavior for the given object 504; and (ii) compare the respective simulated behavior of the given object 504 during that following modelling iteration with the respective past behavior thereof during the first past iteration 501.

For example, the server 235 can be configured to substitute the respective past behavior of the given object 504 during the second modelling iteration 603 with the first simulated behavior, thereby causing the given object 504 to be resting during the second modelling iteration 603.

At the same time, during the second modelling iteration 603, using the given new version of the motion planning algorithm 460, the server 235 can be configured to determine a second simulated trajectory for the vehicle 220 including second modelled kinematic data for the vehicle 220, with which the vehicle 220 continues moving in the first direction 510 while the given object 504 is resting. As it can be appreciated, by assigning the first simulated behavior to the given object 504, visual representations of the vehicle 220 and the given object 504 would not overlap as the vehicle 220 moves along modelled trajectories.

Finally, during the third modelling iteration 605, the server 235 can be configured to generate a third simulated trajectory for the vehicle 220 including third modelled kinematic data, with which the vehicle 220 proceeds in the first direction 510 in the past road section 502. Also, as mentioned above, during the third modelling iteration 605, the server 235 can be configured to re-determine whether a current simulated behavior of the given object 504 corresponds to the respective past behavior thereof during the first past iteration 501. More specifically, during the third modelling iteration 605, the server 235 can be configured to: (i) determine, using the second MLA 360, based on the third simulated trajectory of the vehicle 220, a third simulated behavior for the given object 504; and (ii) determine whether the third simulated behavior of the given object 504 during the third modelling iteration 605 differs from the respective past behavior of the given object 504 during the first past iteration 501.

For example, as at the third modelling iteration 605 the second direction 512 is free of the vehicle 220, using the second MLA 360, the server 235 can be configured to determine the third simulated behavior for the given object 504 that corresponds to the respective past behavior thereof during the first past iteration 501, that is, moving along the second direction 512 to cross the past road section 502 at the crosswalk.

In doing so, the server 235 can be configured to continue modelling the movement of the vehicle 220 for further modelling iterations, adjusting the behaviors of the past surrounding objects to current simulated trajectories of the vehicle 220, thereby generating, based on the ground-truth simulated environment 500, a respective instance of the modified simulated environment 600. According to certain non-limiting embodiments of the present technology, the server 235 can be configured to continue modelling the movement of the vehicle 220 for further modelling iterations of the plurality of modelling iterations until an occurrence of a stopping event.

In some non-limiting embodiments of the present technology, the stopping event can be associated with safety of a given simulated trajectory of the vehicle 220. For example, the stopping event can comprise an accident between the vehicle 220 and an other object (not depicted) in the past road section 502 in the modified simulated environment 600. Let it be assumed that, at the first modelling iteration 601, the other object also intended to move in the second direction 512; however, was invisible to the vehicle 220, such as obscured by the given object 504. In such a case, the server 235 might be unable to determine a respective simulated behavior for the other object; and either during the first modelling iteration 601 or one of the second and third modelling iterations 603, 605, the other object could start moving in the second direction 512 and collide with the vehicle 220.

Other examples of the stopping event can include, without limitation: reaching a predetermined jerk value of the vehicle 220 along the simulated trajectory, reaching a predetermined number of lane changes, an occurrence of traffic rules violation, crossing, by the vehicle 220, a predetermined safety zone defined around another road user in the past road section 502, and the like.

According to certain non-limiting embodiments of the present technology, in response to the occurrence of the stopping event, the server 235 can be configured to: (i) abort modelling the motion of the vehicle 220 using the given new version of the motion planning algorithm 460; (ii) remove the given new version of the motion planning algorithm 460 from further consideration for generating actual trajectories for the vehicle 220; and (iii) proceed to test an other new version of the motion planning algorithm 460 in the ground-truth simulated environment 500. In other words, in these embodiments, the server 235 can be configured to: (i) undo all the modifications to the ground-truth simulated environment 500 made during testing the given new version of the motion planning algorithm 460; and (ii) start testing the other new version thereof from the very beginning as described above.

However, if after reaching a threshold predetermined number of modelling iterations of using the given new version of the motion planning algorithm 460, such as 100, 5 000, or 1 000 000, as an example, the stopping event has not occurred, in some non-limiting embodiments of the present technology, the server 235 can be configured to save the given new version of the motion planning algorithm 460 in the memory 130 of the server 235 for further use in generating the actual trajectories for navigating the vehicle 220 during the runtime. In other words, if the given new version of the motion planning algorithm 460 has passed the testing in the ground-truth simulated environment 500, the server 235 can be configured to transmit this version of the motion planning algorithm 460 to the electronic device 210, thereby enabling the processor 110 of the electronic device 210 to use the given new version of the motion planning algorithm 460 for generating actual trajectories for the vehicle 220 as described above with reference to FIG. 4.

In some non-limiting embodiments of the present technology, the server 235 can further be configured to test the other new version of the motion planning algorithm 460 in the modified simulated environment 600, generated during the testing of the given new version of the motion planning algorithm 460.

Thus, by doing so, the server 235 can be configured to generate the modified simulated environment 600 representative of realistic conditions for modelling motion of the vehicle 220 along simulated trajectories generated by the new versions of the motion planning algorithm 460. Based on the so modelled motion of the vehicle 220, the server 235 can be configured either to reject the given new version of the motion planning algorithm 460 from further use or save it for further determining in-use trajectories for the vehicle 220 in the runtime.

### Method

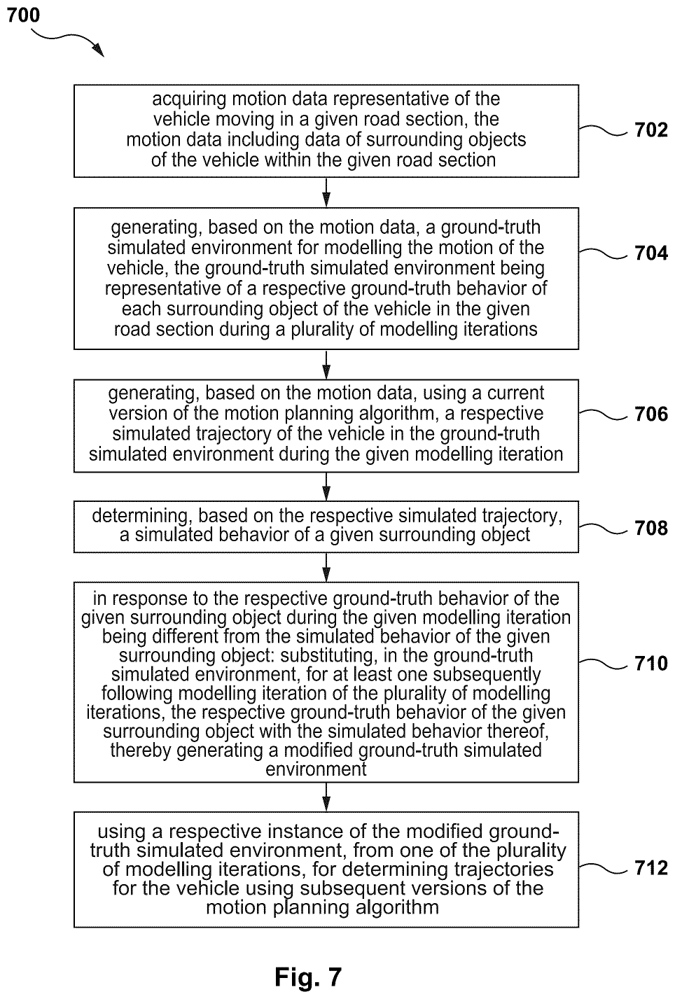

Given the architecture and the examples provided hereinabove, it is possible to execute a method for determining trajectories for the vehicle 220. With reference now to FIG. 7, there is depicted a flowchart of a method 700, according to certain non-limiting embodiments of the present technology. The method 700 can be executed by the server 235.

### STEP 702: ACQUIRING MOTION DATA REPRESENTATIVE OF THE VEHICLE MOVING IN A GIVEN ROAD SECTION, THE MOTION DATA INCLUDING DATA OF SURROUNDING OBJECTS OF THE VEHICLE WITHIN THE GIVEN ROAD SECTION

The method 700 commences at step 702 with the server 235 being configured to acquire the past sensed data representative of past motion of the vehicle 220 in the past road section 502. As mentioned hereinabove, the past sensed data can be generated by the plurality of sensor systems 280 of the vehicle 220, received by the processor 110 of the electronic device 210, and transmitted to the server 235.

As mentioned further above, the past sensed data can include data representative of: a location of the given past surrounding object, such as the given object 504; the respective object class of the given object 504; and the respective past behavior of the given object 504 during each past iteration of the plurality of past iterations of generating past trajectories for the vehicle 220, such as one of the first, second, and third past iterations 501, 503, and 505, as described in detail above with reference to FIG. 5.

The method 700 hence advances to step 704.

STEP 704: GENERATING, BASED ON THE MOTION DATA, A GROUND-TRUTH SIMULATED ENVIRONMENT FOR MODELLING THE MOTION OF THE VEHICLE, THE GROUND-TRUTH SIMULATED ENVIRONMENT BEING REPRESENTATIVE OF A RESPECTIVE GROUND-TRUTH BEHAVIOR OF EACH SURROUNDING OBJECT OF THE VEHICLE IN THE GIVEN ROAD SECTION DURING A PLURALITY OF MODELLING ITERATIONS

At step 704, according to certain non-limiting embodiments of the present technology, the server 235 can be configured to generate, based on the past sensed data, the ground-truth simulated environment 500, as described above with reference to FIG. 5. The ground-truth environment 500 is representative of the actual past motion of the vehicle 220 and the respective past behaviors of the past surrounding objects thereof, such as that of the given object 504, during each one of the first, second, and third past iterations 501, 503, and 505.

The method 700 hence advances to step 706.

### STEP 706: GENERATING, BASED ON THE MOTION DATA, USING A CURRENT VERSION OF THE MOTION PLANNING ALGORITHM, A RESPECTIVE SIMULATED TRAJECTORY OF THE VEHICLE IN THE GROUND-TRUTH SIMULATED ENVIRONMENT DURING THE GIVEN MODELLING ITERATION

At step 706, according to certain non-limiting embodiments of the present technology, the server 235 can be configured to start testing the given new version of the motion planning algorithm 460 that can be used, by the processor 110 of the electronic device 210, for generating trajectories for the vehicle 220. More specifically, at step 706, the server 235 can be configured to generate, using the given new version (or otherwise a current version) of the motion planning algorithm 460, the first simulated trajectory for the vehicle 220 for the first modelling iteration 601 in the ground-truth simulated environment 500. As mentioned above with reference to FIG. 6, the first modelling iteration 601 can be equal to or different from the first past iteration 501.

In the example of FIG. 6, the server 235 has generated the first simulated trajectory including the first kinematic data for the vehicle 220, with which the vehicle 220 would move in the first direction 510 during the first modelling iteration 501 faster than during the first past iteration 501.

The method 700 thus proceeds to step 708.

### STEP 708: DETERMINING, BASED ON THE RESPECTIVE SIMULATED TRAJECTORY, A SIMULATED BEHAVIOR OF A GIVEN SURROUNDING OBJECT

At step 708, using the second MLA 360, based on the first simulated trajectory of the vehicle 220, the server 235 can be configured to determine the first simulated behavior of the given object 504 for the first modelling iteration. As mentioned above with reference to FIG. 6, as chances of collision between the given object 504 and the vehicle 220 given the first simulated trajectory thereof are comparatively high, the server 235 can be configured to determine the first simulated behavior for the given object 504 including resting in the initial position at the beginning of the first modelling iteration 601.

The method 700 hence advances to step 710.

STEP 710: IN RESPONSE TO THE RESPECTIVE GROUND-TRUTH BEHAVIOR OF THE GIVEN SURROUNDING OBJECT DURING THE GIVEN MODELLING ITERATION BEING DIFFERENT FROM THE SIMULATED BEHAVIOR OF THE GIVEN SURROUNDING OBJECT: SUBSTITUTING, IN THE GROUND-TRUTH SIMULATED ENVIRONMENT, FOR AT LEAST ONE SUBSEQUENTLY FOLLOWING MODELLING ITERATION OF THE PLURALITY OF MODELLING ITERATIONS, THE RESPECTIVE GROUND-TRUTH BEHAVIOR OF THE GIVEN SURROUNDING OBJECT WITH THE SIMULATED BEHAVIOR THEREOF, THEREBY GENERATING A MODIFIED GROUND-TRUTH SIMULATED ENVIRONMENT

At step 710, according to certain non-limiting embodiments of the present technology, the server 235 can be configured to determine whether the first simulated behavior of the given object 504 is different from the respective past behavior thereof during the first past iteration 501.

In the examples of FIGS. 5 and 6 described above, the first simulated behavior of the given object 504 during the first modelling iteration 601, which is resting, is different from the respective past behavior of the given object 504 during the first past iteration 501, which was moving in the second direction 512. In response, according to certain non-limiting embodiments of the present technology, the server 235 can be configured to substitute the respective past behavior of the given object 504 with the first simulated behavior thereof for at least one subsequent modelling iteration of the plurality of modelling iterations. For example, the server 235 can be configured to assign the first simulated behavior to the given object 504 for the second modelling iteration 603.

Thus, by modifying the behavior of the given object 504 in the ground-truth simulated environment 500, the server 235 is configured to generate the respective instance of the modified simulated environment 600.

Further, in some non-limiting embodiments of the present technology, the server 235 can be configured to substitute the respective past behavior of the given object 504 for the predetermined number of subsequent modelling iterations, such as 1, 5, or 10. Once the predetermined number of subsequent modelling iterations has passed, during the following modelling iteration, the server 235 can be configured to: (i) re-determine the respective simulated behavior for the given object 504; and (ii) compare the respective simulated behavior of the given object 504 during that following modelling iteration with the respective past behavior thereof during the first past iteration 501.

For example, as mentioned further above with reference to FIG. 6, during the third modelling iteration 605, the server 235 can be configured to generate the third simulated trajectory for the vehicle 220 including the third modelled kinematic data, with which the vehicle 220 proceeds in the first direction 510 in the past road section 502. Subsequently, the server 235 can be configured to determine, based on the third simulated trajectory of the vehicle 220, using the second MLA 360, the third simulated behavior for the given object 504; and (ii) determine whether the third simulated behavior of the given object 504 during the third modelling iteration 605 differs from the respective past behavior of the given object 504 during the first past iteration 501.

For example, as at the third modelling iteration the second direction 512 has been free of the vehicle 220, using the second MLA 360, the server 235 can be configured to determine the third simulated behavior for the given object 504 that corresponds to the respective past behavior thereof during the first past iteration 501, that is, moving along the second direction 512 to cross the past road section 502 at the crosswalk.

By doing so, the server 235 can be configured to continue modelling the motion of the vehicle 220 using the given new version of the motion planning algorithm 460 for further modelling iterations of the plurality of modelling iterations until the stopping event, such as an accident associated with the vehicle 220, occurs.

The method 700 hence advances to step 712.

### STEP 712: USING A RESPECTIVE INSTANCE OF THE MODIFIED GROUND-TRUTH SIMULATED ENVIRONMENT, FROM ONE OF THE PLURALITY OF MODELLING ITERATIONS, FOR DETERMINING TRAJECTORIES FOR THE VEHICLE USING SUBSEQUENT VERSIONS OF THE MOTION PLANNING ALGORITHM

At step 712, in the absence of occurrence of the stopping event, according to certain non-limiting embodiments of the present technology, the server 235 can be configured to save the respective instance of the modified simulated environment 600 for testing subsequent new versions of the motion planning algorithm 460.

Also, if the stopping event has not occurred, while the server 235 tested the given new version of the motion planning algorithm 460, the server 235 can further be configured to save the given new version of the motion planning algorithm 460 for further use in generating in-use trajectories for the vehicle 220 during the runtime.

However, if the stopping event has occurred, the server 235 can be configured to abort modelling the movement of the vehicle 220 using the given new version of the motion planning algorithm 460 and remove it from further consideration for use in determining future trajectories for the vehicle 220.

The method 700 thus terminates.

Thus, certain non-limiting embodiments of the method 700 allow safely modelling motion of the vehicle 220 along newly generated trajectories in a realistic simulated environment.

Modifications and improvements to the above-described implementations of the present technology may become apparent to those skilled in the art. The foregoing description includes example implementations of the present technology and in no way intends to be limiting. The scope of the present technology is therefore intended to be limited solely by the scope of the appended claims.

While the above-described implementations have been described and shown with reference to particular steps performed in a particular order, it will be understood that some of these steps may be combined, sub-divided, or re-ordered without departing from the teachings of the present technology. Accordingly, the order and grouping of the steps is not a limitation of the present technology.

The invention claimed is:

1. A computer-implemented method for determining a trajectory for a vehicle using a motion planning algorithm, the method comprising:
acquiring motion data representative of the vehicle moving in a given road section,
the motion data including data of surrounding objects of the vehicle within the given road section;
generating, based on the motion data, a ground-truth simulated environment for modelling the motion of the vehicle,
the ground-truth simulated environment being representative of a respective ground-truth behavior of each surrounding object of the vehicle in the given road section during a plurality of modelling iterations;
executing, during a given modelling iteration of the plurality of modelling iterations:
generating, based on the motion data, using a current version of the motion planning algorithm, a respective simulated trajectory of the vehicle in the ground-truth simulated environment during the given modelling iteration;
determining, based on the respective simulated trajectory, a simulated behavior of a given surrounding object;
in response to the respective ground-truth behavior of the given surrounding object during the given modelling iteration being different from the simulated behavior of the given surrounding object:
substituting, in the ground-truth simulated environment, for at least one subsequently following modelling iteration of the plurality of modelling iterations, the respective ground-truth behavior of the given surrounding object with the simulated behavior thereof, thereby generating a modified ground-truth simulated environment;
using a respective instance of the modified ground-truth simulated environment, from one of the plurality of modelling iterations, for determining trajectories for the vehicle using subsequent versions of the motion planning algorithm.

2. The method of claim 1, wherein the generating the ground-truth simulated environment comprises determining, for each surrounding object in the given road section, a respective object class.

3. The method of claim 2, wherein the determining the respective object class for each surrounding object comprises soliciting a respective label therefor from a human assessor.

4. The method of claim 2, wherein:
the motion data includes bounding boxes representative of the surrounding objects; and
the determining the respective object class for each surrounding object comprises applying a machine-learning algorithm (MLA) that has been trained to determining the respective object class of the given surrounding object based on a respective bounding box representative thereof.

5. The method of claim 1, wherein the determining the simulated behavior for the given surrounding object comprises applying an MLA that has been trained to determine actual behaviors of surrounding objects based on a current trajectory of the vehicle.

6. The method of claim 1, wherein the substituting comprises substituting until, at a given subsequent modelling iteration of the plurality of modelling iterations, a respective simulated behavior of the given surrounding object corresponds to the respective ground-truth behavior thereof for the given modelling iteration.

7. The method of claim 1, further comprising, in response to a stopping event during the given modelling iteration:
aborting modelling the motion of the vehicle without executing a subsequent modelling iteration; and
removing the current version of the motion planning algorithm from further consideration for determining the trajectories for the vehicle.

8. The method of claim 7, wherein the stopping event comprises an occurrence of an accident associated with the vehicle during the given modelling iteration.

9. A server for determining a trajectory for a vehicle using a motion planning algorithm, the server comprising at least one processor and at least one non-transitory computer-readable memory storing executable instructions, which, when executed by the at least one processor, cause the server to:
acquire motion data representative of the vehicle moving in a given road section,
the motion data including data of surrounding objects of the vehicle within the given road section;
generate, based on the motion data, a ground-truth simulated environment for modelling the motion of the vehicle,
the ground-truth simulated environment being representative of a respective ground-truth behavior of each surrounding object of the vehicle in the given road section during a plurality of modelling iterations;
execute, during a given modelling iteration of the plurality of modelling iterations:
generating, based on the motion data, using a current version of the motion planning algorithm, a respective simulated trajectory of the vehicle in the ground-truth simulated environment during the given modelling iteration;
determining, based on the respective simulated trajectory, a simulated behavior of a given surrounding object;
in response to the respective ground-truth behavior of the given surrounding object during the given modelling iteration being different from the simulated behavior of the given surrounding object:
substituting, in the ground-truth simulated environment, for at least one subsequently following modelling iteration of the plurality of modelling iterations, the respective ground-truth behavior of the given surrounding object with the simulated behavior thereof, thereby generating a modified ground-truth simulated environment;
use a respective instance of the modified ground-truth simulated environment, from one of the plurality of modelling iterations, for determining trajectories for the vehicle using subsequent versions of the motion planning algorithm.

10. The server of claim 9, wherein to generate the ground-truth simulated environment, the at least one processor causes the server to determine, for each surrounding object in the given road section, a respective object class.

11. The server of claim 10, wherein to determine the respective object class for each surrounding object, the at least one processor causes the server to solicit a respective label therefor from a human assessor.

12. The server of claim 10, wherein:
the motion data includes bounding boxes representative of the surrounding objects; and
to determine the respective object class for each surrounding object, the at least one processor causes the server to apply a machine-learning algorithm (MLA) that has been trained to determining the respective object class of the given surrounding object based on a respective bounding box representative thereof.

13. The server of claim 9, wherein to determine the simulated behavior for the given surrounding object, the at least one processor causes the server to apply an MLA that has been trained to determine actual behaviors of surrounding objects based on a current trajectory of the vehicle.

14. The server of claim 9, wherein the substituting comprises substituting until, at a given subsequent modelling iteration of the plurality of modelling iterations, a respective simulated behavior of the given surrounding object corresponds to the respective ground-truth behavior thereof for the given modelling iteration.

15. The server of claim 9, wherein, in response to a stopping event during the given modelling iteration, the at least one processor further causes the server to:
abort modelling the motion of the vehicle without executing a subsequent modelling iteration; and
remove the current version of the motion planning algorithm from further consideration for determining the trajectories for the vehicle.

16. The server of claim 15, wherein the stopping event comprises an occurrence of an accident associated with the vehicle during the given modelling iteration.
